(19) United States
(12) Patent Application Publication
(10) Pub. No.: US 2005/0052912 A1
(43) Pub. Date: Mar. 10, 2005

(54) Circuit and system for addressing memory modules

(76) Inventors: Mike Cogdill, Longmont, CO (US); Idis Ramona Martinez, Roseville, CA (US); Lidia Mihaela Warnes, Wilton, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/655,964

(22) Filed: Sep. 4, 2003

(51) Int. Cl. G11C 7/00

(52) U.S. Cl. 365/202

(57) ABSTRACT

A circuit and system addressing multiple computer memory modules on the same bus while maintaining proper timing. The circuit includes a transmission line having a dampening impedance between a driver and a branch point of the transmission line. The circuit also has a termination impedance having one end coupled to the transmission line between the dampening impedance and the branch point. The transmission line has branches from the branch point. Individual branches are coupled to at least one memory module interface.

### TECHNICAL FIELD

The present invention relates to the field of computer systems. Specifically, embodiments of the present invention relate to a circuit and system for addressing multiple computer memory modules on the same bus while maintaining proper timing.

### BACKGROUND ART

FIG. 1 illustrates a conventional circuit 100 for addressing several memory modules 110. For example, the configuration of FIG. 1 may be used for double data rate (DDR) synchronous dynamic random access memory (SDRAM). Typically, the configuration consists of two to four dual inline memory modules (DIMM) that are connected together by daisy chaining the modules together as shown in FIG. 1.

Resistors are used to avoid problematic reflections and to properly terminate the address signal. A series resistor 120 between the driver 125 and the memory modules 1 10 serves to dampen reflected signals coming back from the memory modules 110. The parallel resistor 130 coupled to the terminating voltage 140 serves to properly terminate the signal and typically has an impedance to match that of the transmission line 150.

Such a conventional system functions well when the number of memory modules 110 is limited to no more than four memory modules 110. However, the need for ever more memory has led to a desire to place more than four memory modules together in a fashion such that they can all be addresses by a single driver.

Unfortunately, if more than four modules are daisy chained in the configuration of FIG. 1, the distance between the memory modules 110 leads to unacceptable skew. That is, it takes too long for the address signal to travel from the first to the fifth or more memory module, given the timing budget.

One conventional technique to increase the number of memory modules in the overall system is to add an additional driver to the system such that a few more memory modules can be addressed within the timing budget. However, this solution is undesirable because the additional driver requires additional space, which is limited in many computer systems.

Thus, one problem with conventional methods of addressing memory in a computer system is that timing skew limits how many memory modules can be addressed using a single driver. Another problem with conventional techniques is that too much space is required by the number of drivers that are required to address the desired number of memory modules.

### DISCLOSURE OF THE INVENTION

The present invention pertains to a circuit and system for a heavily loaded memory module address bus. In one embodiment, the circuit comprises a transmission line having a dampening impedance between a driver and a branch point of the transmission line. The circuit also has a termination impedance having one end coupled to the transmission line between the dampening impedance and the branch point. The transmission line has branches from the branch point. Each branch couples to at least one memory module interface.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 illustrates a conventional configuration for addressing memory modules.

FIG. 2 is a diagram of a circuit for addressing multiple computer memory modules on the same bus while maintaining proper timing, according to embodiments of the present invention.

FIG. 3A is a diagram of a location for impedances for addressing multiple computer memory modules on the same bus while maintaining proper timing, according to embodiments of the present invention.

FIG. 3B is a diagram of an alternative location for impedances for addressing multiple computer memory modules on the same bus while maintaining proper timing, according to embodiments of the present invention.

FIG. 4 is a side view of a system for addressing multiple computer memory modules on the same bus while maintaining proper timing, according to an embodiment of the present invention.

### DETAILED DESCRIPTION OF THE INVENTION

In the following detailed description of embodiments of the present invention, a circuit and system for addressing multiple computer memory modules on the same bus while maintaining proper timing, numerous specific details are set forth in order to provide a thorough understanding of the present invention. However, embodiments of the present invention may be practiced without these specific details or by using alternative elements or methods. In other instances well known methods, procedures, components, and circuits have not been described in detail as not to unnecessarily obscure aspects of the present invention.

Embodiments of the present invention reduce skew when addressing multiple computer memory modules on the same bus while maintaining proper timing, as compared to conventional solutions. Embodiments of the present invention use a single driver to address more than four memory modules. Embodiments of the present invention allow termination resistors to be placed relatively far from the memory modules being addressed. Thus, embodiments of the present invention provide more freedom in selecting the location of termination resistors.

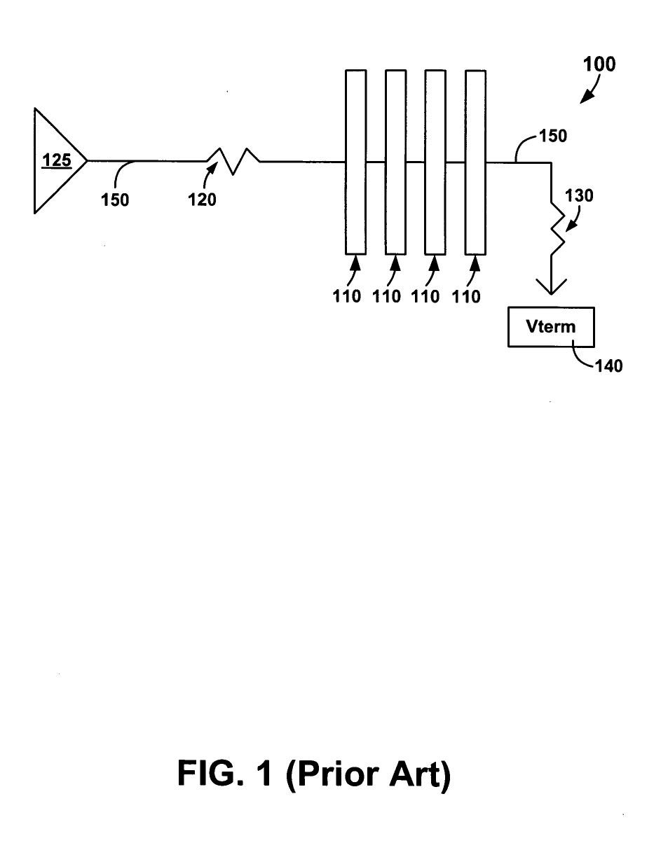

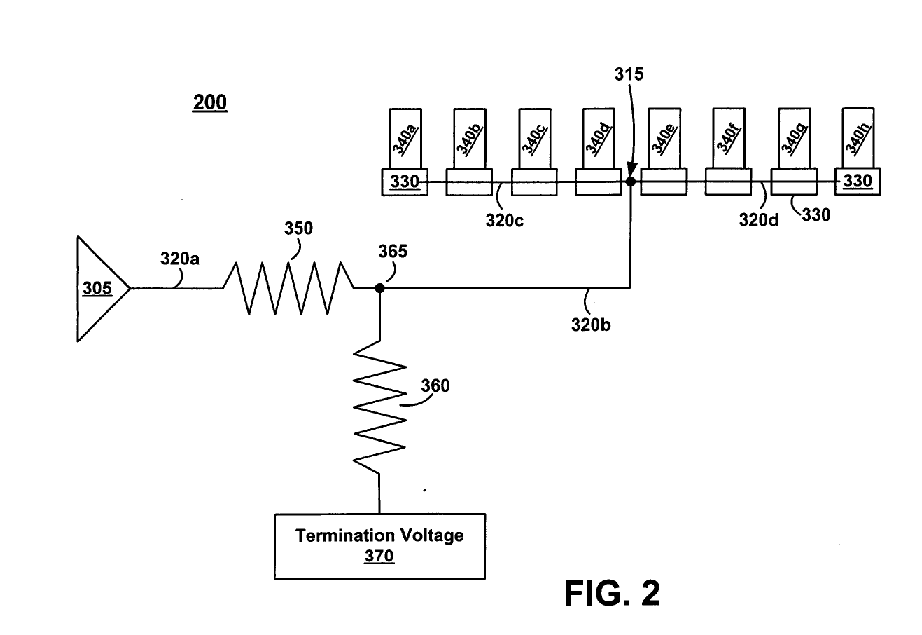

FIG. 2 is a circuit 200 for accessing memory modules 340, according to an embodiment of the present invention. The circuit 200 allows the number of memory modules that are addressed to be doubled, as compared to the conventional circuit in FIG. 1, without an increase in the timing skew. Moreover, the configuration of dampening and termination impedances allows for signal transmission with adequate signal integrity to address the memory modules 340.

The circuit 200 has a transmission line 320 that is coupled at one end to a driver 305 and coupled to interfaces 330 that are able to receive memory modules 340. The transmission line 320 is unidirectional in embodiments of the present invention. The transmission line 320 has a branch point 315 from which two branches 320c, 320d of the transmission line extend. A first branch 320c extends from the branch point 315 to memory module connector 340a. A second branch 320d extends from the branch point 315 to memory module connector 340i. The first branch 320c electrically connects to memory module connectors 340a, 340b, 340c, and 340d. The second branch 320d electrically connects to memory module connectors 340e, 340f, 340g, and 340h. Thus, each branch 320c and 320d is used to address four memory modules, such that a single driver 305 is used to address eight memory modules 340. Thus, the number of memory modules 340 that can be addressed by a single driver 305 is doubled over the conventional circuit of FIG. 1, while still maintaining proper timing. The two branches 320c, 320d of the transmission line are also referred to herein as an address line. Embodiments of the present invention are not limited to the transmission line having only two branches.

Still referring to FIG. 2, the transmission line 320 comprises a series dampening impedance 350. The dampening impedance 350 is between a segment of the transmission line 320a coupled to the driver 305 and a segment of the transmission line 320b between the dampening impedance 350 and the branch point 315. The circuit 300 also has a parallel termination impedance 360 having one end coupled to a node 365 on the transmission line 320 between the dampening impedance 350 and the branch point 315. The termination impedance 360 is connected to the dampening impedance 350, in one embodiment of the present invention. However, it is not required that the dampening impedance 350 and the termination impedance 360 be connected without any intervening element. The other end of the termination impedance 360 is coupled to a termination voltage 370.

Referring briefly to FIG. 1, the purpose of the pull-up parallel termination resistor 130 is to terminate the signal at the end of the transmission line 115. As such, it is not considered intuitive to place a parallel termination resistor on the same side of the memory modules as the driver. Referring now to FIG. 2, the termination impedance 360 is placed on the same side of the memory modules 340 as the driver 305. As positioned, the combination of the series dampening impedance 350 and the parallel termination impedance 360 prevents, or at least reduces, reflections from the memory modules 340 from travelling back to the driver 305 in the region of the transmission line 320a between the parallel termination resistor 360 and the driver 305. There may be some reflections in the region of the transmission line 320b between the parallel termination resistor 360 and the branch point 315, as well as on the branches of the transmission line 320c and 320d.

However, embodiments of the present invention are configured such that reflections between the parallel termination resistor 360 and the memory modules 340 do not cause significant signal integrity problems. For example, the memory modules 340 are located very close to each other relative to the size of the wavelength of a typical signal.

The transmission line 320 branches at branch point to achieve a symmetrical configuration in the various branches of the data line 320, in embodiments in accordance with the present invention. Thus, not only is skew reduced when addressing the memory modules, but the symmetry reduces the complexity in analyzing the system during design and test phases.

In the conventional circuit of FIG. 1, the resistors 120, 130 should be near the memory modules 110. However, with some system designs it is not practical or even possible to locate the dampening and termination impedances near the memory modules. Embodiments of the present invention allow the dampening and termination impedances to be a long distance from the memory modules. In one embodiment of the present invention the distance from point 365 at which the termination impedance 360 connects to the transmission line 320 to the branch point 315 is greater than the length of the branches of the transmission line 320c, 320d.

Moreover, in embodiments of the present invention, the configuration of the series dampening impedance 350 and the parallel termination impedance 360 provides flexibility in controlling the magnitude of the signal on the transmission line 320 not available in the conventional circuit of FIG. 1. The series dampening impedance 350 and the parallel termination impedance 360 form a voltage divider. By selecting appropriate impedance values for the series dampening impedance 350 and the parallel termination impedance 360, the magnitude of the signal on the transmission line 320 is controlled, according to an embodiment of the present invention.

For clarity, FIG. 2 only depicts a single set of components. Embodiments of the present invention have numerous sets of components each for delivering address data to separate pins of respective memory module interfaces 330.

There may be more or fewer memory module connectors 330 than shown in FIG. 2. Moreover, it is not required that all of the memory module connectors 330 contain memory modules 340.

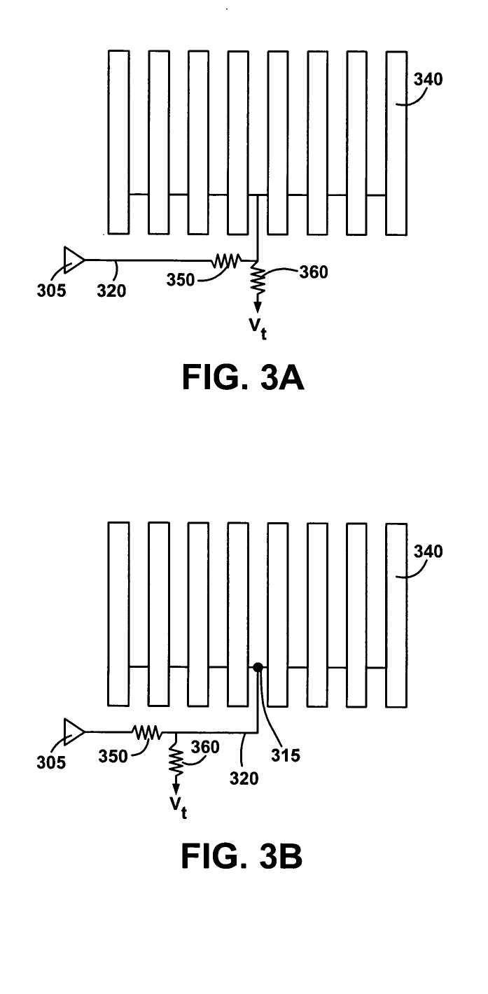

Moreover, the dampening and termination impedances can be located on the side of the memory module connectors rather than on the end of the memory modules. For example, referring to the conventional circuit of FIG. 1, the series dampening resistor 120 is adjacent to one end of the chain of memory modules 110 and the parallel termination resistor 130 is at the other end of the chain of memory modules 110. Referring to FIG. 3A, the series dampening impedance 350 and the parallel termination impedance 360 are located adjacent to the side of the chain of memory modules 340.

In FIG. 3A, the series dampening impedance 350 and the parallel termination impedance 360 are near the middle of the chain of memory modules 340. However, the impedances can be located anywhere along the edge from the first to last memory module 340. In FIG. 3B, the series dampening impedance 350 and the parallel termination impedance 360 are located adjacent to the side of the chain of memory modules 340 at a spot between the first and second memory modules 340 in the chain. As it is not required that the dampening impedance 350 and the parallel termination impedance 360 be located close to the branch point 315, embodiments of the present invention provide greater freedom in locating the impedances than does the convention circuit of FIG. 1. Thus, the embodiments of FIGS. 3A and 3B are exemplary of many possible locations for the series dampening impedance 350 and the parallel termination impedance 360.

In embodiments of the present invention, the waveform that is transmitted on the transmission line 320 is a square wave that is used as a data signal. That is, the rising or falling edges of the waveform are not used for clocking purposes. Therefore, the rising and falling edges of the waveform are not critical. However, the top and bottom of the waveform are significant for the data value to be registered properly. Even if there is some deformity in the edges of the waveform, the data value will still be interpreted properly if the tops and bottoms of the waveform do not experience significant distortion. For example, the data value will still be interpreted properly if the tops and bottoms of the waveform are within specification for the memory modules 340 in the circuit 300. The present invention provides for such a waveform in which the tops and bottoms of the waveform have a distortion that is small enough so as to not cause improper values to be registered.

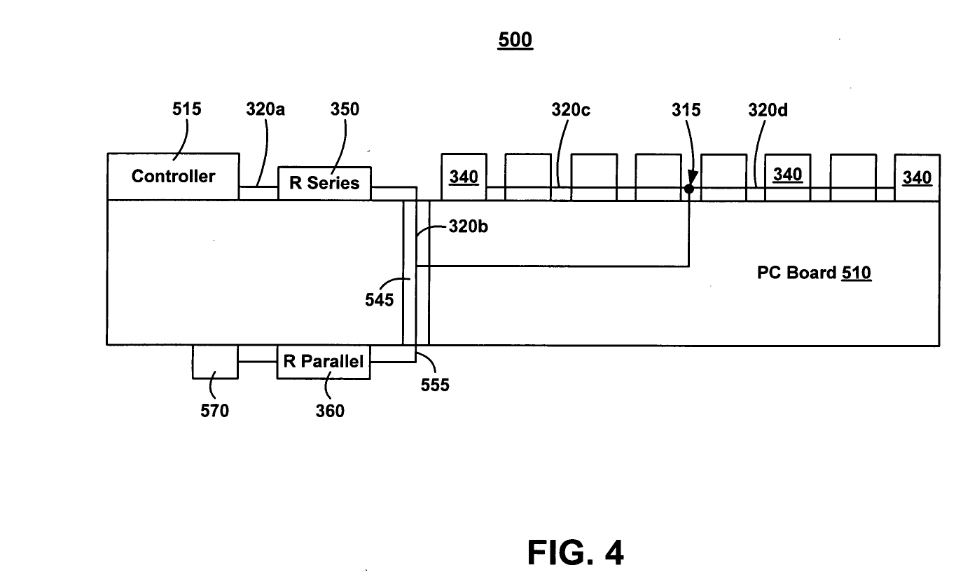

FIG. 4 is a side view of a system 500 for accessing memory modules, according to an embodiment of the present invention. FIG. 4 illustrates one possible placement for the dampening and termination impedances with respect to a printed circuit board. The system 500 includes a printed circuit board (PC board) 510 upon which the dampening and termination impedances 350, 360 are mounted on opposite sides. Also mounted on the PC board 510 are a controller 515 and memory module connectors 340.

The dampening and termination impedances 350, 360 are electrically coupled by a line through the via 545 in the PC board 510. Placing the dampening and termination impedances 350, 360 on opposite sides of the PC board 510 may allow for a more compact PC board 510 than if both impedances 350, 360 are placed on the same side of the PC board 510, although it is not required that the impedances be located on opposite sides of the PC board 510.

The system 500 includes a transmission line 320 that couples the controller 515 with the memory module connectors 340. A portion of the transmission line 320a is coupled between the controller 515 and the dampening impedance 350. The dampening impedance 350 may also be referred to as a series impedance. Another portion of the transmission line 550b is coupled between the dampening impedance 350 and the memory module connectors 340. This portion of the transmission line 550b run partway through the via 545. A first end of the termination impedance 360 is electrically coupled to the transmission line 550 by termination impedance line 555. A second end of the termination impedance 360 is electrically connected to a termination voltage terminal 570.

The second portion of the transmission line 550 couples to a branch point 315 of the transmission line 320, which branches into two separate parts 320c and 320d. Each branch 320c, 320d of the transmission line couples to four memory module connectors 340, in this embodiment. However, the present invention is not limited to a branch being connected to four memory module connectors. Moreover, the present invention is not limited to only two branches. The embodiment of FIG. 4 allows the controller 515 to comprise a single driver that addresses eight memory modules while staying within the timing budget. The memory modules are not depicted in FIG. 4. In one embodiment in accordance with the invention, the memory modules are dual inline memory modules (DIMMs). The memory itself is double data rate (DDR) synchronous dynamic random access memory (SDRAM), in accordance with an embodiment of the present invention.

While the present invention has been described in particular embodiments, it should be appreciated that the present invention should not be construed as limited by such embodiments, but rather construed according to the below claims.

1. A circuit for a memory module address bus comprising:
a transmission line comprising a dampening impedance between a driver and a branch point of said transmission line; and
a termination impedance having one end coupled to said transmission line between said dampening impedance and said branch point;
said transmission line having branches from said branch point, wherein ones of said branches are coupled to at least one memory module interface.

2. The circuit of claim 1, wherein said transmission line is unidirectional.

3. The circuit of claim 1, wherein said ones of said branches are coupled to two memory module interfaces.

4. The circuit of claim 1, wherein said ones of said branches are coupled to three memory module interfaces.

5. The circuit of claim 1, wherein said ones of said branches are coupled to four memory module interfaces.

6. The circuit of claim 1, wherein the distance from said branch point to said one end of said termination impedance is greater than the length of said branches.

7. The circuit of claim 1, wherein said one end of said termination impedance is connected to said dampening impedance.

8. A circuit for reducing skew when addressing a memory module comprising:
a plurality of memory modules;
an address line coupling said memory modules;
a transmission line having a series impedance and a parallel impedance in a stub configuration; and
said transmission line having a first end coupled to a driver and a second end connected at a point on said address line to reduce skew when addressing a memory module.

9. The circuit of claim 8, wherein said second end of said transmission line is connected at substantially the midpoint of said address line.

10. The circuit of claim 8, wherein said transmission line is uni-directional.

11. The circuit of claim 8, wherein said parallel impedance is connected to said series impedance.

12. The circuit of claim 8, wherein said plurality of memory modules is an odd number and wherein said second end of said transmission line is connected to said address line at the middle memory module.

13. The circuit of claim 8, wherein said plurality of memory modules is an even number and wherein said second end of said transmission line is connected to said address line at a point substantially midway between two memory modules closest to the mid-point of said address line.

14. A system for addressing memory modules comprising:
a bus controller;
a transmission line comprising a series impedance between a driver and a branch point of said transmission line; and
a parallel impedance having a first end coupled to said transmission line between said dampening impedance and said branch point and a second end coupled to a termination voltage terminal;
said transmission line having branches from said branch point, wherein ones of said branches are coupled to at least one memory module interface.

15. The system of claim 14, wherein two branches of said branches from said branch point have substantially the same length.

16. The system of claim 14, wherein said transmission line is uni-directional.

17. The circuit of claim 14, wherein said ones of said branches are coupled to two memory module interfaces.

18. The system of claim 14, wherein said ones of said branches are coupled to three memory module interfaces.

19. The system of claim 14, wherein said ones of said branches are coupled to four memory module interfaces.

20. The system of claim 14, wherein the distance from said branch point to said first end of said parallel impedance is greater than the length of said branches.

21. The system of claim 14, wherein said first end of said parallel impedance is connected to said series impedance.

22. The system of claim 14, wherein said parallel impedance and said series resistance are mounted on opposite sides of a printed circuit board.
